(19) United States
(12) Patent Application Publication
(10) Pub. No.: US 2003/0007528 A1
(43) Pub. Date: Jan. 9, 2003

(54) Surface emitting semiconductor laser device

(76) Inventors: Seiji Uchiyama, Tokyo (JP); Hitoshi Shimizu, Tokyo (JP)

Correspondence Address: KNOBBE MARTENS OLSON & BEAR LLP, 2040 MAIN STREET, FOURTEENTH FLOOR, IRVINE, CA, 92614, US

(21) Appl. No.: 10/171,019

(22) Filed: Jun. 11, 2002

(30) Foreign Application Priority Data
Jun. 12, 2001 (JP) 2001-176670
May 22, 2002 (JP) 2002-147247

(51) Int. Cl. H01S 5/00

(52) U.S. Cl. 372/46

(57) ABSTRACT

A surface emitting semiconductor laser device including a substrate and a layer structure formed thereon, the layer structure including an active layer, p-type and n-type distributed Bragg reflector (DBR) sandwiching therebetween the active layer, and first and second selectively-oxidized layers disposed within or in vicinities of the p-type and n-type DBRs, respectively, each of the p-type and n-type DBRs including a plurality of layer pairs each including a lower reflection layer and a higher reflection layer, each of the selectively-oxidized layers including a central AlₓGa₁₋ₓAs area (x≧0.98) and a peripheral oxide area formed by oxidizing an outer periphery of the central AlₓGa₁₋ₓAs area, the peripheral oxide area of the first selectively-oxidized layers has a width smaller than a width of the peripheral oxide area of the second selectively-oxidized layer. The surface emitting semiconductor laser device can be obtained having the operational voltage which can be maintained lower and the excellent single transverse mode.

### BACKGROUND OF THE INVENTION

(a) Field of the Invention

The present invention relates to a surface emitting semiconductor laser device with a current confinement oxide layer, and more in particular to the a surface emitting semiconductor laser device with the current confinement oxide layer having an excellent single transverse mode.

(b) Description of the Related Art

As shown in FIG. 1, a conventional surface emitting semiconductor laser device 10 has a layer structure, overlying a p-type GaAs substrate 12, including a bottom distributed Bragg reflector (hereinafter referred to as “DBR”) 14 having a multiple-layer film including 20 to 30 pairs of p-type Al_{y}Ga_{1-y}As/Al_{z}Ga_{1-z}As (y>z, y≦0.95), a current confinement structure including an AlAs layer 16 and an AlOₓ layer 18 formed by oxidizing the outer periphery of the AlAs layer 16, a p-type cladding layer 20, an active layer 22, an n-type cladding layer 24 and a top DBR 26 having a multiple-layer film including 20 to 30 pairs of n-type Al_{y}Ga_{1-y}As/Al_{z}Ga_{1-z}As (y>z, y≦0.95).

The AlOₓ current confinement layer 18 is formed by selectively oxidizing the Al in the AlAs layer 16 along the side walls of the air post structure. The central part of the AlAs layer 16 remains unoxidized to form a current injection path.

A ring-shaped n-side electrode 28 is formed on the top DBR 26, and a p-side electrode 30 is formed on the bottom surface of the p-type GaAs substrate 12.

The operation of the surface emitting semiconductor laser device 10 should be in the basic mode by stabilizing the transverse mode, i.e. in the single transverse mode, in order to use the laser device 10 as an optical source.

The diameter of the active region (current injection region) 16 surrounded by the AlOₓ current confinement layer 18 should be 10 μm or less for achieving the single transverse mode.

Although a smaller diameter of 10 μm or less improves the single transverse mode of the surface emitting semiconductor laser device to lower the threshold current thereof, problems arise such as increase of the operational voltage and deterioration of the temperature characteristic due to the rise of an electric resistance caused by the reduction of the active region and due to the rise of the thermal resistance caused by the reduction of the thermal conductivity of the oxide layer.

Thus, in place of reducing the diameter of the active region to be 10 μm or less, reduction of the aperture diameter of the n-side electrode or usage of a dielectric aperture is attempted to stabilize the transverse mode.

However, in the above proposals, the apertures in these electrodes or the dielectric films formed by the photolithographic and etching process generate a deviation more than a submicron order between the center of the active region and the center of the aperture. Accordingly, in reality, the stabilization of the transverse mode is difficult.

Another method is reported in which a cladding layer is thickened to obtain a single transverse mode (E. J. Ebeling et al., “High Performance VCSELs for Optical Data Links”, OECC 2000, pp.518-519, 2000).

This method is effective at a lower output range wherein the single transverse mode uses 9 mA for the injection current at the highest.

A further method is reported in which several pairs of mirrors formed on a current confinement layer are oxidized to form apertures to make a single transverse mode in a surface emitting semiconductor laser device formed on an n-type substrate (N. Nishiyama et el., “Multi-Oxide layer Structure for Single-Mode Operation In Vertical-Cavity Surface-Emitting Lasers”, IEEE Photonics technol. Lett., vol.12, pp.606-608).

The apertures in this method formed in a p-type semiconductor multi-layered film increase the resistance, and the aperture diameters are not decreased. The current flowing in the injection current region in which the single transverse mode is stabilized is lower than 2 mA, and this method is effective also only for the lower output range.

As described above, realization of the surface emitting semiconductor laser device is difficult which stably emits laser in the single transverse mode in the higher output range.

### SUMMARY OF THE INVENTION

It is an object of the present invention to provide a surface emitting semiconductor laser device having a current confinement oxide layer and is capable of stably operating in a single transverse mode.

In the present invention, a surface emitting semiconductor laser device is provided which includes a substrate and a layer structure formed thereon, the layer structure including an active layer, p-type and n-type distributed Bragg reflector (DBR) sandwiching therebetween the active layer, and first and second selectively-oxidized layers disposed within or in vicinities of the p-type and n-type DBRs, respectively, each of the p-type and n-type DBRs including a plurality of layer pairs each including a lower reflection layer and a higher reflection layer, each of the selectively-oxidized layers including a central AlₓGa₁₋ₓAs area (x≧0.98) and a peripheral oxide area formed by oxidizing an outer periphery of the central AlₓGa₁₋ₓAs area, the peripheral oxide area of the first selectively-oxidized layers has a width smaller than a width of the peripheral oxide area of the second selectively-oxidized layer.

In accordance with the present invention, the surface emitting semiconductor laser device has an excellent single transverse mode and a lower operational voltage by using the oxide narrowing layers formed within or in the vicinity of the n-type semiconductor multi-layered film and within or in the vicinity of the p-type semiconductor multi-layered film as the optical confinement layer and the current confinement layer, respectively.

The above and other objects, features and advantages of the present invention will be more apparent from the following description.

### BRIEF DESCRIPTION OF DRAWINGS

FIG. 1 is a sectional view showing a conventional surface emitting semiconductor laser device.

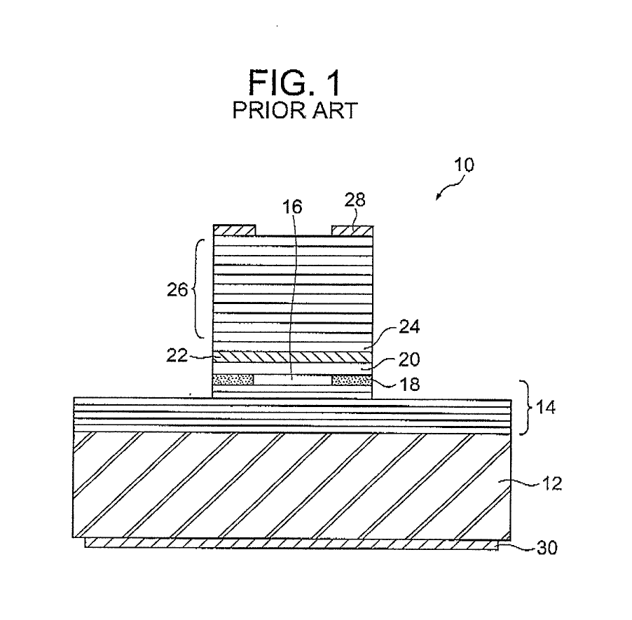

FIG. 2 is a sectional view showing a surface emitting semiconductor laser device in accordance with an Embodiment of the present invention.

FIGS. 3A and 3B show layer structures of compound semiconductor layers in FIG. 2 constituting a bottom DBR and a top DBR, respectively.

FIG. 4 is a sectional view showing a surface emitting semiconductor laser device in accordance with another Embodiment of the present invention.

FIGS. 5A and 5B show layer structures of compound semiconductor layers in FIG. 4 constituting a bottom DBR and a top DBR, respectively.

### PREFERRED EMBODIMENTS OF THE INVENTION

Then, the configuration of a semiconductor laser device in accordance with embodiments of the present invention will be described referring to the annexed drawings.

### Embodiment 1

A surface emitting semiconductor laser device 40 of the Embodiment features an Al oxide layer acting as an optical confinement layer.

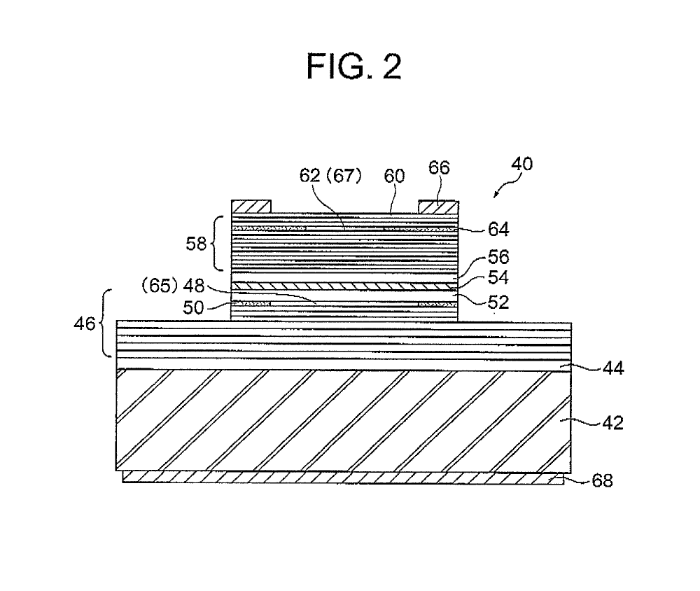

As shown in FIG. 2, the surface emitting semiconductor laser device 40 has a layer structure, overlying a p-type (100) (or 10° off or less) GaAs substrate 42, including a p-type GaAs buffer layer 44, a bottom DBR 46, a current confinement structure having a p-type AlₓGa₁₋ₓAs (x≧0.98) layer 48 and a first AlOₓ layer 50 formed by selectively oxidizing an outer periphery of the AlₓGa₁₋ₓAs layer 48, a bottom cladding layer 52, an active layer 54, a top cladding layer 56, a top DBR 58 and an n-type GaAs contact layer 60.

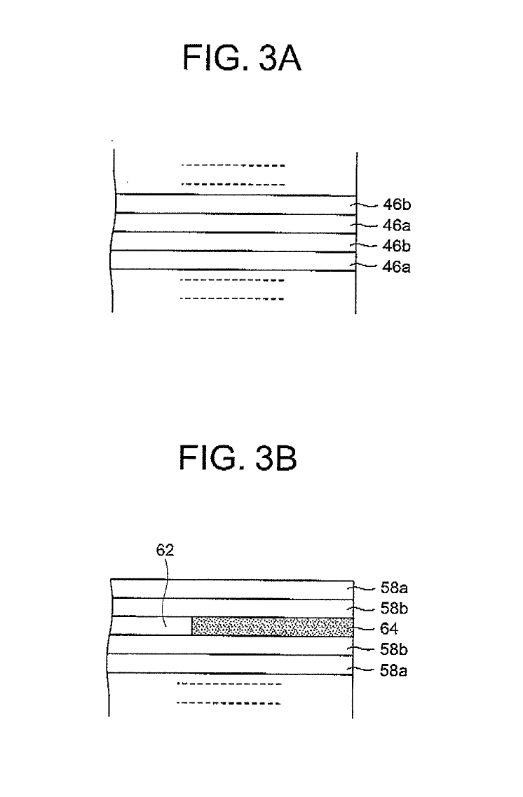

As shown in FIG. 3A, the bottom DBR 46 is configured as a semiconductor multi-layer film including 20 to 40 pairs of a p-type Al_{y}Ga_{1-y}As layer 46a acting as a lower reflection layer and a p-type Al_{z}Ga_{1-z}As layer 46b acting as a higher reflection layer (y>z, y≦0.95).

As shown in FIG. 3B, the top DBR 58 is configured as a semiconductor multi-layer film including 15 to 30 pairs of an n-type Al_{y}Ga_{1-y}As layer 58a acting as a lower reflection layer and an n-type Al_{z}Ga_{1-z}As layer 58b acting as a higher reflection layer (y>z, z≦0.95).

In place of one of the plenty of the n-type Al_{y}Ga_{1-y}As layers 58a in the top DBR 58, an n-type AlₓGa₁₋ₓAs (x≧0.98) layer 62 is formed and the outer periphery of the AlₓGa₁₋ₓAs layer is selectively oxidized to form a second AlOₓ layer 64.

The n-type GaAs contact layer 60, the top DBR 58, the n-type AlₓGa₁₋ₓAs layer 62 and the AlOₓ layer 64, the top cladding layer 56, the active layer 54, the bottom cladding layer 52, the p-type AlₓGa₁₋ₓAs layer 48, the current confinement structure of the first AlOₓ layer 50 and the upper part of the bottom DBR 46 are configured as a mesa post structure.

The first AlOₓ layer 50 is formed by selectively oxidizing the Al in the p-type AlₓGa₁₋ₓAs layer 48 along the side walls of the mesa post structure to generate a region no current flows.

The central region of the p-type AlₓGa₁₋ₓAs layer 48 remains unoxidized to form a current injection path having a diameter of 15 μm (hereinafter referred to as “second aperture 65”). Thereby, the region no current flows is restricted and the diameter of the light emitting region is determined.

The second AlOₓ layer 64 is formed by selectively oxidizing the Al in the n-type AlₓGa₁₋ₓAs layer 62 along the side walls of the mesa post structure.

The central region of the n-type AlₓGa₁₋ₓAs layer 62 remains unoxidized to form the n-type AlₓGa₁₋ₓAs layer 62 having a diameter of 10 μm (hereinafter referred to as “first aperture 67”).

The bottom cladding layer 52, the active layer 54 and the top cladding layer 56 form a resonator of the surface emitting semiconductor laser device 40.

A ring-shaped n-side electrode 66 is formed on the n-type GaAs contact layer 60, and a p-side electrode 68 is formed on the bottom surface of the p-type GaAs substrate 42.

The refractivity of the second AlOₓ layer is up to 1.7, and the refractivity of the first aperture 67 of the n-type AlₓGa₁₋ₓAs layer 62 where the central part is unoxidized is up to 3. Accordingly, the rays propagate through the first aperture (n-type AlₓGa₁₋ₓAs layer) 62.

A similar phenomenon takes place in the first AlOₓ layer 50.

Then, the diameters of the second aperture 65 and of the first aperture 67 are defined as “D” and “d”, respectively.

The diameter of the light emitting region is restricted by the current flow limited by the second aperture having the diameter “D”, thereby reducing the threshold current. While the transverse mode is controlled by the refractivity difference between the first AlOₓ layer 50 and the second aperture 65, the single transverse mode can be obtained only when the diameter “D” is about 5 μm or less because the refractivity difference between the oxidized layer and the unoxidized layer is larger.

However, if the diameter “D” is made to be up to 5 μm, the thermal resistance increases to worsen the temperature characteristics and the electric resistance increases to raise the operational voltage. If the diameter “D” is made to be about 15 μm to maintain the lower operational voltage, the multiple transverse modes are generated.

On the contrary, in the present Embodiment, the higher order mode of the transverse mode is cut off to realize the single transverse mode by making the diameter “D” of the second aperture 65 to be 15 μm for the current confinement and further making the diameter “d” of the first aperture 67 formed in the bottom DBR 46 to be 10 μm.

In other words, the oxide width of the first AlOₓ layer 50 surrounding the second aperture 65 is smaller than the second AlOₓ layer 64 surrounding the first aperture 67 in the n-type bottom DBR 46.

If the diameter “d” of the first aperture is reduced, the electric resistance does not increase significantly and the operational voltage does not increase because of the n-type.

The current confinement structure formed by the AlₓGa₁₋ₓAs layer 48 and the first AlOₓ layer 50 in the present Embodiment is formed between the bottom DBR 46 and the bottom cladding layer 52. However, the current confinement structure may be formed in the bottom DBR 46.

The optical confinement structure formed by the n-type AlₓGa₁₋ₓAs layer 62 and the second AlOₓ layer 64 is formed in place of one of the plenty of the n-type Al_{y}Ga_{1-y}As layers 58a in the top DBR 58. However, the n-type AlₓGa₁₋ₓAs layer may be formed between the top cladding layer 56 and the top DBR 58 and the second AlOₓ layer 64 is formed by selectively oxidizing the outer periphery of the n-type AlₓGa₁₋ₓAs layer.

### Embodiment 2

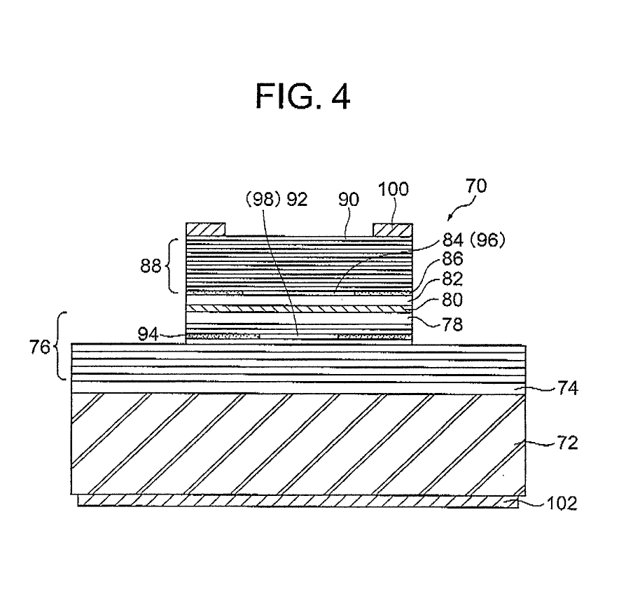

As shown in FIG. 4, a surface emitting semiconductor laser device 70 of the Embodiment, another example of the present invention, is formed on an n-type GaAs substrate and has a basic configuration in which the bottom DBR and the top DBR of the surface emitting semiconductor laser device in Embodiment 1 are replaced with each other.

That is, as shown in FIG. 4, the surface emitting semiconductor laser device 70 has a layer structure, overlying an n-type (100) (or 10° off or less) GaAs substrate 72, including an n-type GaAs buffer layer 74, a bottom DBR 76, a bottom cladding layer 78 formed by an n-type AlₓGa₁₋ₓAs (x≧0.98) layer, an active layer 80, a top cladding layer 82 formed by an n-type AlₓGa₁₋ₓAs (x≧0.98) layer, a current confinement structure having a p-type AlₓGa₁₋ₓAs (x≧0.98) layer 84 and a first AlOₓ layer 86 formed by selectively oxidizing an outer periphery of the AlₓGa₁₋ₓAs layer 84, a top DBR 88 and a p-type GaAs contact layer 90.

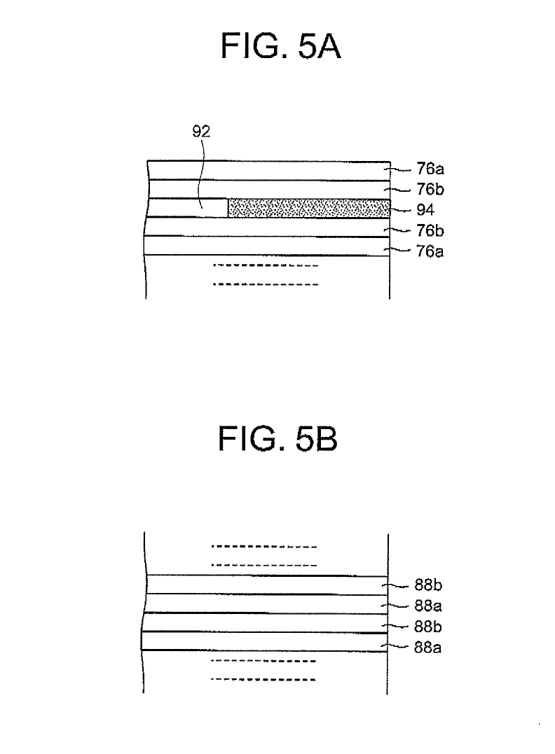

As shown in FIG. 5A, the bottom DBR 76 is configured as a semiconductor multilayer film including 15 to 30 pairs of an n-type Al_{y}Ga_{1-y}As layer 76a acting as a lower reflection layer and an n-type Al_{z}Ga_{1-z}As layer 76b acting as a higher reflection layer (y>z, y≦0.95).

As shown in FIG. 5A, in place of one of the n-type Al_{y}Ga_{1-y}As layers 76a constituting the bottom DBR 76 in the mesa post, an n-type AlₓGa₁₋ₓAs (x≧0.98) layer 92 is formed and the outer periphery of the AlₓGa₁₋ₓAs layer is selectively oxidized to form a second AlOₓ layer 94.

As shown in FIG. 5B, the top DBR 88 is configured as a semiconductor multi-layer film including 20 to 40 pairs of an n-type Al_{y}Ga_{1-y}As layer 88a acting as a lower reflection layer and an n-type Al_{z}Ga_{1-z}As layer 88b acting as a higher reflection layer (y>z, z≦0.95).

The p-type GaAs contact layer 90, the top DBR 88, the current confinement structure formed by the p-type AlₓGa₁₋ₓAs layer 84 and the AlOₓ layer 86, the top cladding layer 82, the active layer 80, the bottom cladding layer 78, the n-type AlₓGa₁₋ₓAs layer 92 and the second AlOₓ layer 94 and the upper part of the bottom DBR 76 are configured as a mesa post structure.

The first AlOₓ layer 86 is formed by selectively oxidizing the Al in the p-type AlₓGa₁₋ₓAs layer 84 along the side walls of the mesa post structure to generate a region no current flows.

The central region of the p-type AlₓGa₁₋ₓAs layer 84 remains unoxidized to form a current injection path having a diameter of 15 μm (hereinafter referred to as “second aperture 96”). Thereby, the region no current flows is restricted and the diameter of the light emitting region is determined.

The second AlOₓ layer 94 is formed by selectively oxidizing the Al in the n-type AlₓGa₁₋ₓAs layer 92 along the side walls of the mesa post structure.

The central region of the n-type AlₓGa₁₋ₓAs layer 92 remains unoxidized to form the n-type AlₓGa₁₋ₓAs layer 92 having a diameter of 10 μm (hereinafter referred to as “first aperture 98”).

The bottom cladding layer 78, the active layer 80 and the top cladding layer 82 form a resonator of the surface emitting semiconductor laser device 70.

A ring-shaped p-side electrode 100 is formed on the p-type GaAs contact layer 90, and an n-side electrode 102 is formed on the bottom surface of the n-type GaAs substrate 72.

The refractivity of the second AlOₓ layer 94 is up to 1.7, and the refractivity of the first aperture 98 of the n-type AlₓGa₁₋ₓAs layer 92 where the central part is unoxidized is up to 3. Accordingly, the rays propagate through the unoxidized first aperture (n-type AlₓGa₁₋ₓAs layer) 98 in the center of the mesa post.

A similar phenomenon takes place in the first AlOₓ layer 86.

Then, the diameters of the second aperture 96 and of the first aperture 98 are defined as “D” and “d”, respectively.

The diameter of the light emitting region is restricted by the current flow limited by the second aperture 96 having the diameter “D”, thereby reducing the threshold current. While the transverse mode is controlled by the refractivity difference between the first AlOₓ layer 86 and the second aperture 96, the single transverse mode can be obtained only when the diameter “D” is about 5 μm or less because the refractivity difference between the oxidized layer and the unoxidized layer is larger.

However, if the diameter “D” is made to be up to 5 μm, the thermal resistance increases to worsen the temperature characteristics and the electric resistance increases to raise the operational voltage. If the diameter “D” is made to be about 15 μm to maintain the lower operational voltage, the multiple transverse modes are generated.

On the contrary, in the present Embodiment, the higher order mode of the transverse mode is cut off to realize the single transverse mode by making the diameter “D” of the second aperture 96 to be 15 μm for the current confinement and further making the diameter “d” of the first aperture 98 formed in the bottom DBR 76 to be 10 μm.

In other words, the oxide width of the first AlOₓ layer 86 surrounding the second aperture 96 is smaller than the second AlOₓ layer 94 surrounding the first aperture 98 in the n-type bottom DBR 76.

If the diameter “d” of the first aperture is reduced, the electric resistance does not increase significantly and the operational voltage does not increase because of the n-type.

The current confinement structure formed by the p-type AlₓGa₁₋ₓAs layer 84 and the first AlOₓ layer 86 in the present Embodiment is formed between the top cladding layer 80 and the top DBR 82. However, the current confinement structure may be formed in the bottom DBR 80. In other words, the p-type AlₓGa₁₋ₓAs layer is formed in place of one of the p-type Al_{y}Ga_{1-y}As layers 80a in the bottom DBR 80, and the outer periphery of the p-type AlₓGa₁₋ₓAs layer is oxidized to form the first AlOₓ layer.

The optical confinement structure formed by the n-type AlₓGa₁₋ₓAs layer 92 and the second AlOₓ layer 94 is formed in place of one of the plenty of the n-type Al_{y}Ga_{1-y}As layers 58a in the bottom DBR 76. However, the n-type AlₓGa₁₋ₓAs layer may be formed between the bottom DBR 75 and the bottom cladding layer 78, and the second AlOₓ layer may be formed by selectively oxidizing the outer periphery of the n-type AlₓGa₁₋ₓAs layer.

Since the above embodiment is described only for examples, the present invention is not limited to the above embodiment and various modifications or alterations can be easily made therefrom by those skilled in the art without departing from the scope of the present invention.

What is claimed is:

1. A surface emitting semiconductor laser device comprising a substrate and a layer structure formed thereon, the layer structure including an active layer, p-type and n-type distributed Bragg reflector (DBR) sandwiching therebetween the active layer, and first and second selectively-oxidized layers disposed within or in vicinities of the p-type and n-type DBRs, respectively, each of the p-type and n-type DBRs including a plurality of layer, pairs each including a lower reflection layer and a higher reflection layer, each of the selectively-oxidized layers including a central AlₓGa₁₋ₓAs area (x≧0.98) and a peripheral oxide area formed by oxidizing an outer periphery of the central AlₓGa₁₋ₓAs area, the peripheral oxide area of the first selectively-oxidized layers has a width smaller than a width of the peripheral oxide area of the second selectively-oxidized layer.

2. The surface emitting semiconductor laser device as defined in claim 1, wherein the selectively-oxidized layer replaces the lower reflection layer in each of the p-type and n-type DBRs.

3. The surface emitting semiconductor laser device as defined in claim 1, the first selectively-oxidized layer resides within the p-type DBR and functions as a current confinement layer, and the second selectively oxidized layer resides within the n-type DBR and functions as an optical confinement layer.

4. The surface emitting semiconductor laser device as defined in claim 1, wherein the AlₓGa₁₋ₓAs area of second selectively-oxidized layer has a diameter of 10 μm or less.

5. The surface emitting semiconductor laser device as defined in claim 1, wherein the lower reflection layer and the higher reflection layer are Al_{y}Ga_{1-y}As layer and Al_{z}Ga_{1-z}As layer, respectively, given y and z are such that y>z and 0≦y≦0.95.
